(19) United States
(12) Patent Application Publication
(10) Pub. No.: US 2026/0231777 A1
(43) Pub. Date: Aug. 6, 2026

(54) WAFER-TO-WAFER BONDING ALIGNMENT PATTERN AND RELATED METHODS

(71) Applicant: Taiwan Semiconductor Manufacturing Company Limited, Hsin-Chu (TW)

(72) Inventors: Sz-Fan CHEN, Kaohsiung City (TW); Tzu-Wei YU, Hsinchu City (TW); Chun-Chang CHEN, Tainan City (TW)

(21) Appl. No.: 19/044,664

(22) Filed: Feb. 4, 2025

(51) Int. Cl. H01L 23/544; H01L 23/00; H01L 25/065

(52) U.S. Cl. CPC H10W 46/00; H10W 90/00; H10W 46/301; H10W 80/163; H10W 80/312; H10W 90/297

(57) ABSTRACT

A device is provided. The device includes: a first substrate; a first interconnect structure on the first substrate; a second substrate; a second interconnect structure on the second substrate, the first substrate being bonded to the second substrate by a hybrid bond between the first interconnect structure and the second interconnect structure; an active circuit region in the second substrate, the active circuit region including a via that extends through the second substrate; and at least four alignment patterns that are offset from the via. Each of the alignment patterns includes: a first conductive feature in a first top metal layer of the first interconnect structure; and a second conductive feature in a second top metal layer of the second interconnect structure, the second conductive feature having size that does not exceed that of the first conductive feature.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, 1F, 1G, 1H, 1I, 1J, 1K, 1L, 1M, 1N and 1O illustrate intermediate diagrammatic views of a method of forming an integrated circuit device, in accordance with some embodiments.

FIG. 2 is a flow diagram illustrating a method of forming an integrated circuit device, in accordance with some embodiments.

FIG. 3 is a flow diagram illustrating a method of forming an integrated circuit device, in accordance with some embodiments.

FIG. 4 is a flow diagram illustrating a method of forming an integrated circuit device, in accordance with some embodiments.

FIG. 5 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, wafer-on-wafer (WoW) processing technology, sometimes referred to as 3D wafer stacking, represents an advancement in semiconductor fabrication, allowing for increased transistor density and enhanced device performance. WoW involves stacking multiple wafers, either by directly bonding them or by using intermediate layers like through-silicon vias (TSVs), which are vertical electrical connections through the silicon. WoW processing provides benefits. By stacking wafers, more components can be integrated into a smaller footprint, effectively increasing the number of transistors or other elements per chip area. Reduced interconnect length due to vertical stacking leads to lower power consumption, faster signal transmission, and better overall performance due to decreased parasitic capacitance and inductance. Different types of chips, such as logic, memory, and sensors, can be integrated in a single package, allowing for improved performance characteristics associated with each technology. WoW processing enables formation of complex systems having multiple functionalities within the same package, which is beneficial for applications requiring high data throughput and energy efficiency. WoW processing technology is beneficial for forming advanced, compact, and efficient electronic devices, which may be included in computing, communications, and automotive electronics systems. WoW processing faces challenges in managing thermal issues, achieving high precision in bonding alignment, and providing device reliability over time.

When bonding two wafers to form a vertical wafer stack, good determination of alignment accuracy between the wafers is beneficial to avoid overlay errors when forming additional features post-bonding. Alignment accuracy can include linear terms (e.g., translation, rotation, expansion/contraction) and non-linear terms that can be referred to as “distortion.” To determine overlay shifts at each TSV site, for example, alignment accuracy may be determined by alignment marks that are included in the wafers. As circuit feature sizes shrink and non-linear alignment terms become increasingly associated with overlay errors, including a single alignment mark site for each exposure shot or “field” is increasingly insufficient to obtain precise determination of intra-field alignment accuracy. Measuring bonding alignment accuracy following thinning down of the wafer(s) reduces ability to perform rework, because the thinned down wafer is difficult to debond without cracking. Overlay pilot run data is used to generate a single correction recipe for distortion compensation that is applied to an entire batch of wafers. Overlay feedback data can be provided using a pilot golden correction recipe.

In embodiments of the disclosure, a method of performing WoW processing predicts distortion by using an alignment monitoring pattern for determining bonding alignment accuracy (AA). The alignment monitoring pattern can include at least four alignment marks, at least two of which are intra-field alignment marks. High similarity between bonding AA and overlay (OVL) enables accurate prediction of bonding alignment distortion, which is fed forward to subsequent processes (e.g., photolithography for TSV formation), which reduces rework rate and improves yield. The alignment monitoring pattern provides improved accuracy (e.g., within 1 nanometer). The alignment monitoring pattern can provide measurement at a post-bond stage prior to a thin-down stage, at the thin-down stage and even any backside interconnect stage prior to photolithography. The alignment monitoring pattern has reduced dimensions (e.g., 15 μm×15 μm to 60 μm×60 μm), allowing for intra-field measurement. The alignment monitoring pattern can provide cost reduction due to reduced number of exposure/overlay measurement/rework cycles and improved cycle time. The alignment monitoring pattern can be included in many wafer-on-wafer products.

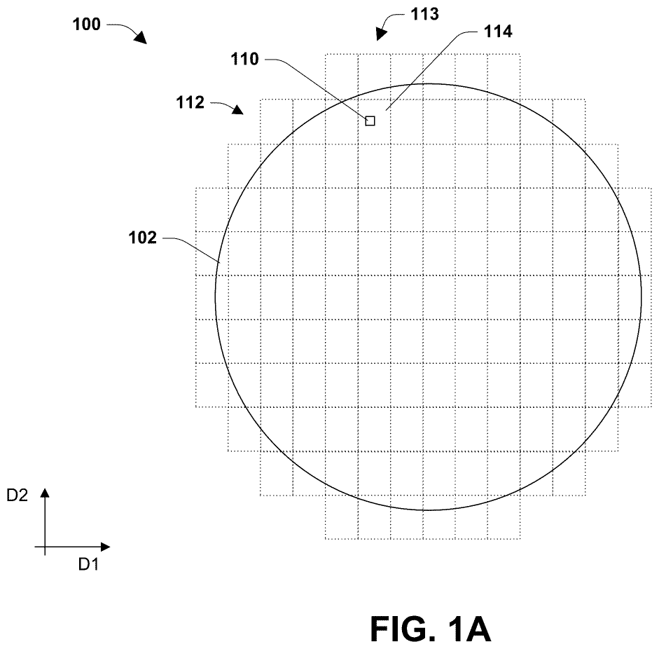

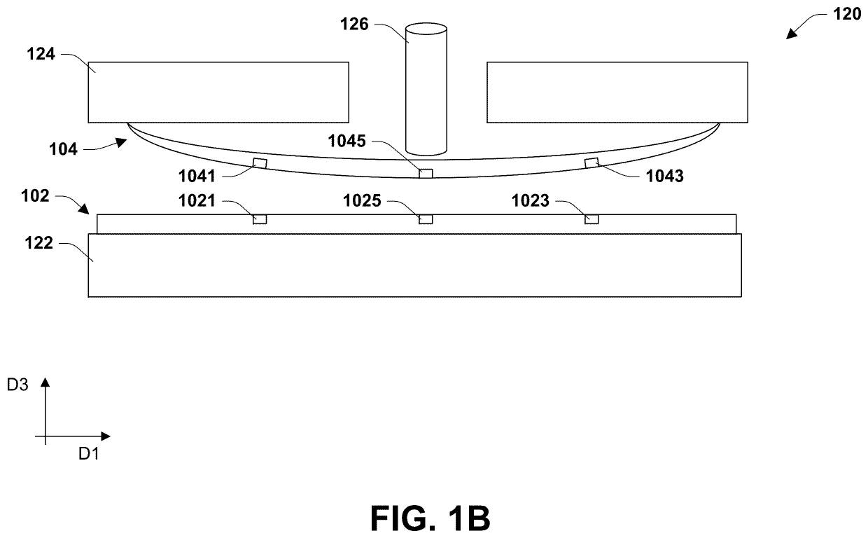

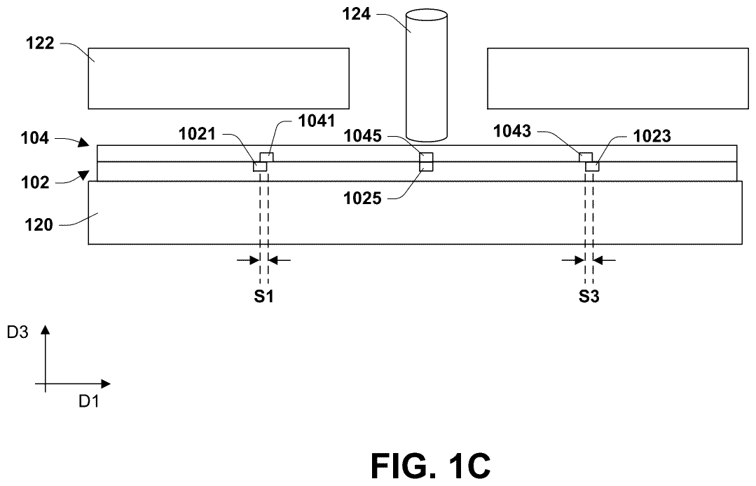

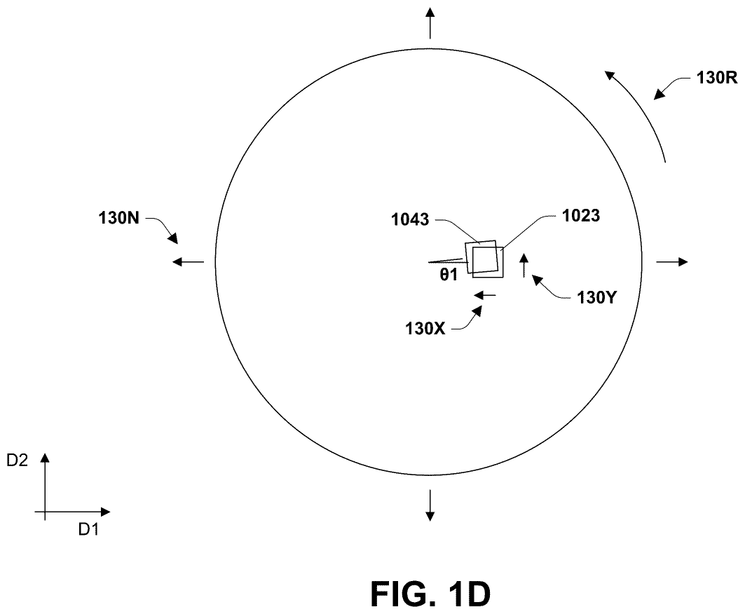

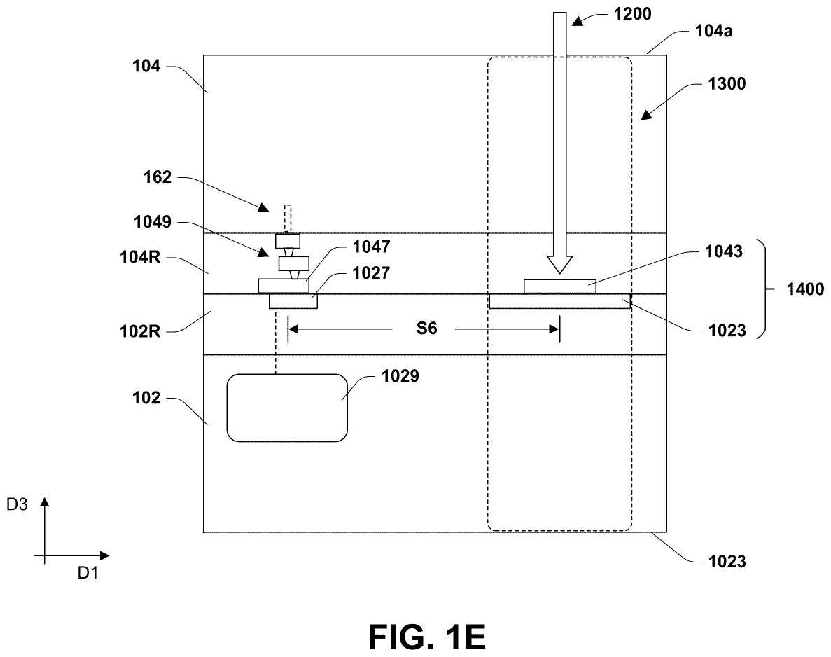

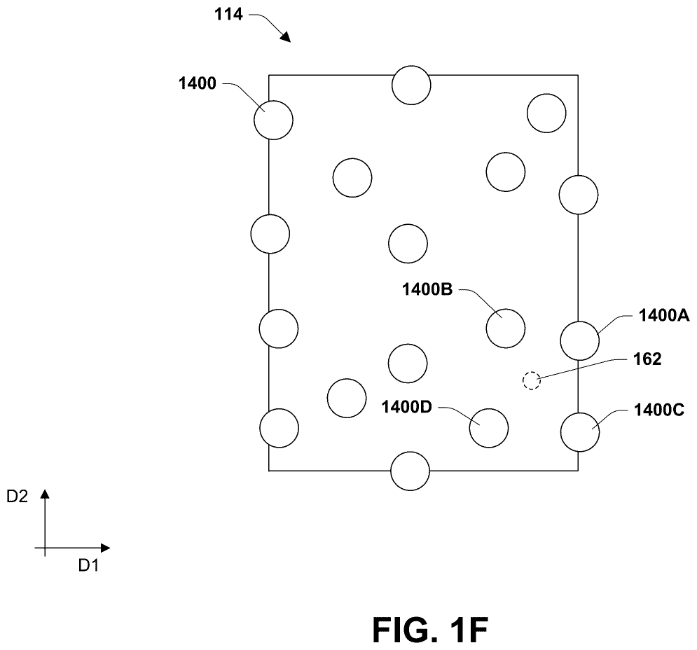

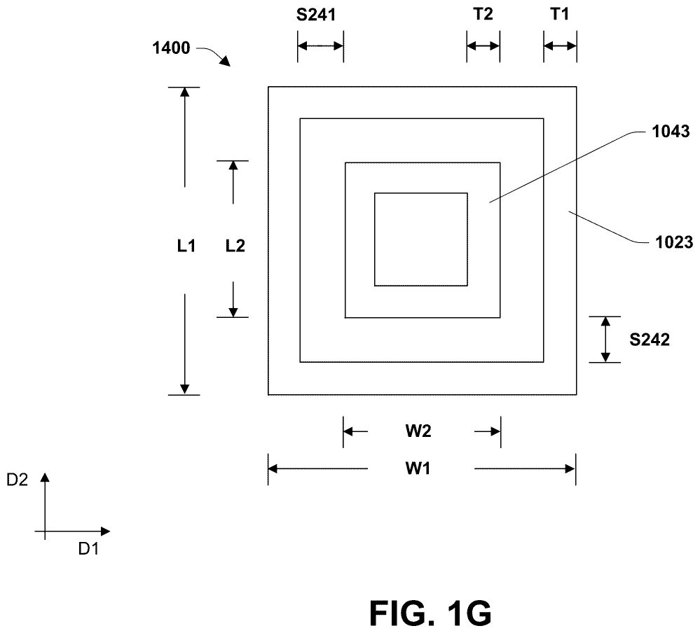

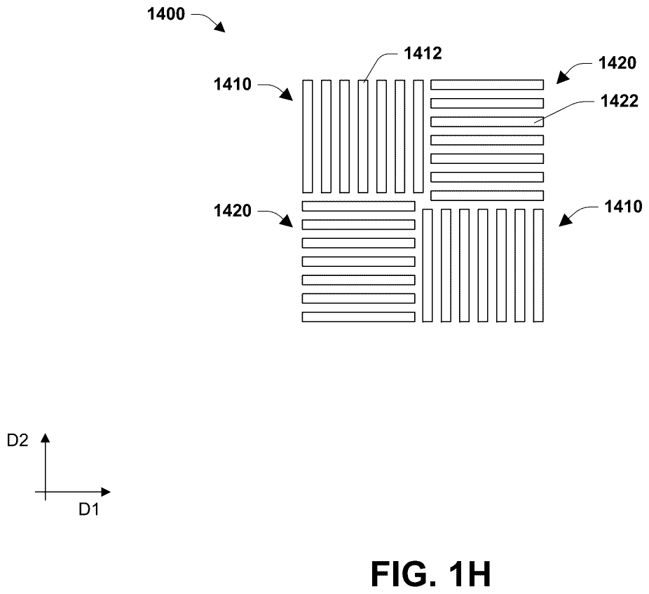

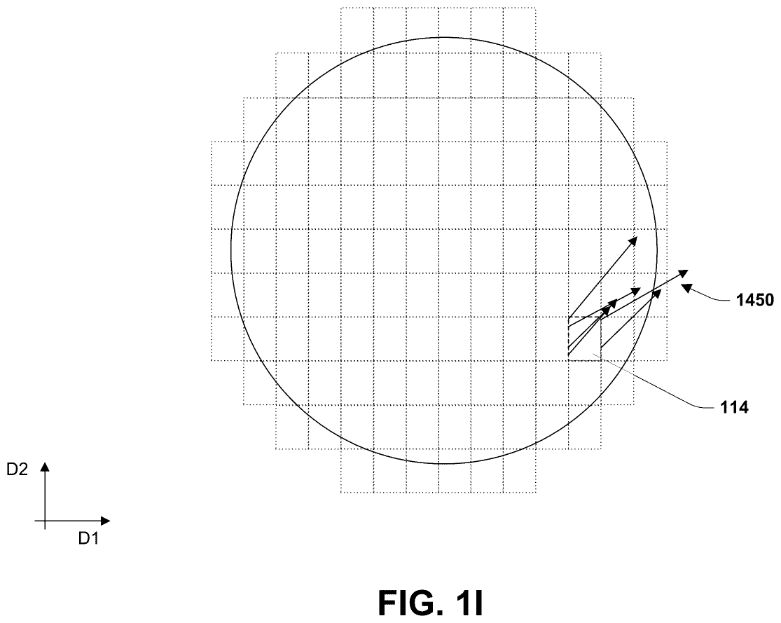

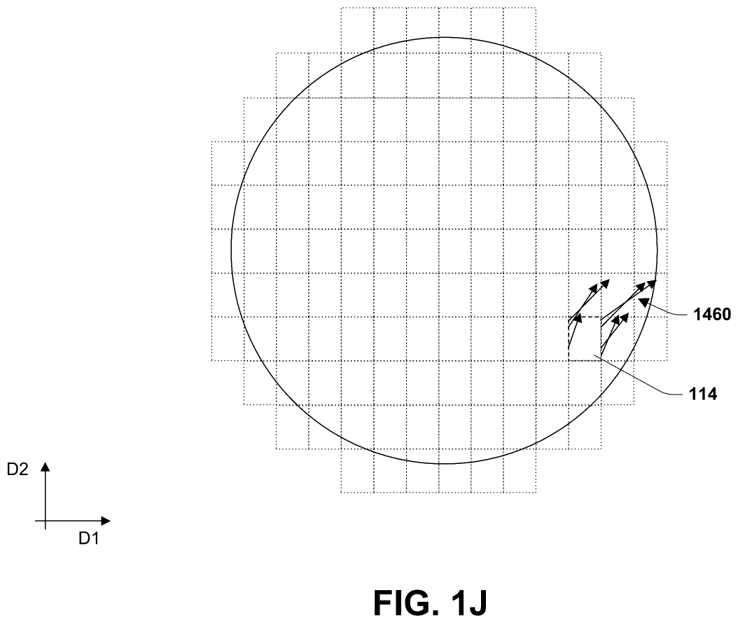

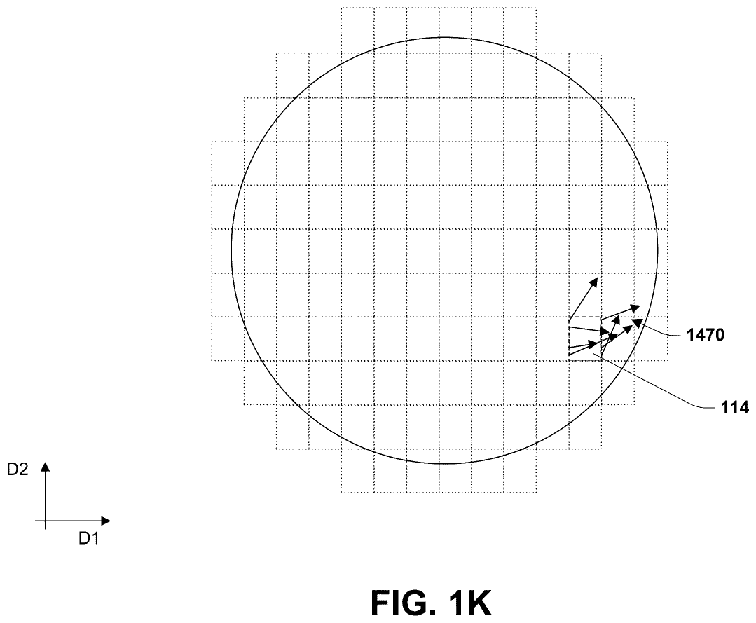

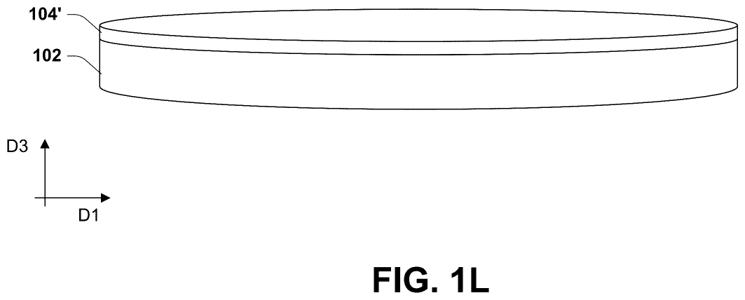

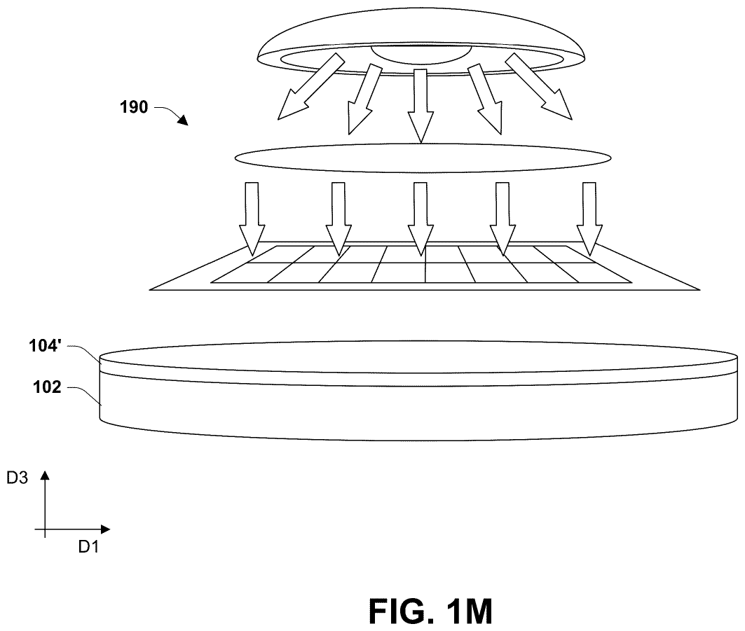

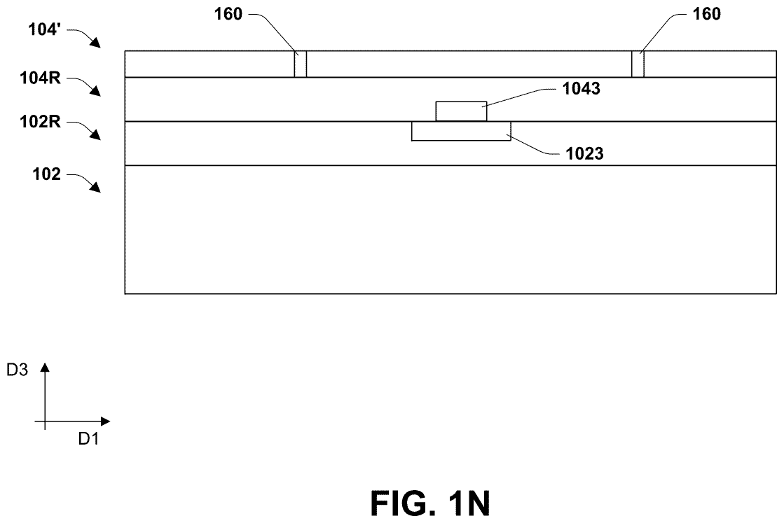

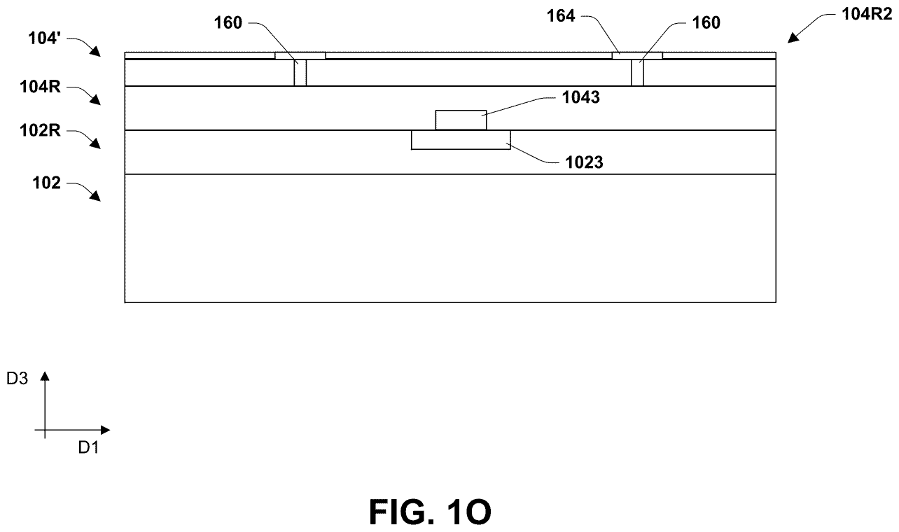

FIGS. 1A, 1B, 1C, 1D, 1E, 1F, 1G, 1H, 1I, 1J, 1K, 1L, 1M, 1N and 1O illustrate intermediate diagrammatic views of a method of forming an integrated circuit device, in accordance with some embodiments.

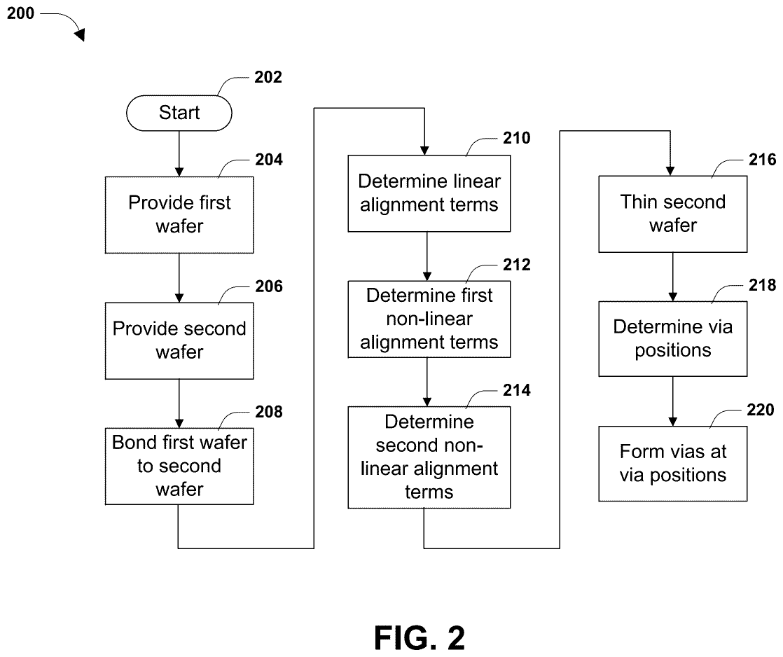

FIG. 2 illustrates a flow diagram of some embodiments of a method 200 for forming an integrated circuit device, in accordance with some embodiments. While method 200 is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

In FIG. 1A, an in-process IC wafer 100 (or simply “the first wafer 100”) is provided, corresponding to act 204 of FIG. 2. The in-process IC wafer 100 can include an integrated circuit die region 110 positioned on and/or in a semiconductor substrate 102. In some embodiments, the in-process IC wafer 100 is formed by process operations, which can include patterning, deposition, cleaning, planarizing, annealing, epitaxial growing, and the like. The process operations form circuit features, such as metal gates, epitaxial source/drains, conductive vias, conductive traces, and the like.

In some embodiments, the semiconductor substrate 102 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor substrate 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor substrate 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate 102 are within the scope of the present disclosure.

In some embodiments, the IC die regions 110 can be in-process dies or completed dies that are to be singulated in a subsequent process operation. The IC die regions 110 can be or include microcontrollers (MCUs), microprocessors (MPUs), graphics processing units (GPUs), artificial intelligence (AI) accelerators, memory ICs, analog ICs, logic ICs, optoelectronics, power management ICs, wireless communication ICs. In some embodiments, the IC die regions 110 are arranged in one or more rows 112 and one or more columns 113. The rows 112 extend along a first direction D1 and are arranged along a second direction D2. The columns 113 extend along the second direction D2 and are arranged along the first direction D1. Each of the IC die regions 110 may be positioned in a photolithography field 114 that has size associated with a single exposure “shot” from a mask. The field 114 may include at least two IC die regions 110. For example, the field 114 may have dimensions of about 26 mm×33 mm and each of the IC die regions 110 may have dimensions of about 10 mm×10 mm or smaller. Other dimensions for the IC die regions 110 are also contemplated as embodiments herein.

In some embodiments, each of the IC die regions 110 includes one or more patterned layers of different materials that are arranged to form electronic circuits. Components of each IC die region 110 of the IC die regions 110 can include transistors, interconnects, capacitors, resistors, inductors and the like. The IC die region 110 can include many material layers, such as the substrate 102, epitaxial layers, isolation layers, gate dielectric layers, gate electrode layers, source/drain layers, contact layers, interconnect layers, dielectric layers, passivation layers and the like. Formation of the material layers can include performing one or more semiconductor processes, such as deposition, photolithography, etching, doping, planarization, and the like. Along a vertical axis that is perpendicular to the major surface of the IC die region 110, from bottom to top, the IC die region 110 can include a device region and an interconnect region on the device region. The device region can generally include the transistors and capacitors, and the interconnect region can generally include the interconnects as well as capacitors, inductors, resistors and the like. The transistors can be or include field effect transistors (FETs), which can include planar transistors, fin FETs (or “FinFETs”), nanostructure FETs (e.g., nanosheet FETs or the like), vertical FETs, and the like. In some embodiments, the interconnect region can include memory devices, such as phase-change random access memory (PCRAM) devices, magnetoresistive random access memory (MRAM) devices, and/or other suitable memory devices.

In some embodiments, prior to bonding the first wafer 100 to a second wafer in a subsequent operation, an interconnect structure or redistribution layer (RDL) structure may be formed on an active surface of the first wafer 100. For example, the first wafer 100 may include a device layer having transistors positioned therein, and may further include a first interconnect structure on the device layer having front-end-of-line (FEOL) interconnects, mid-end-of-line (MEOL) interconnects and back-end-of-line (BEOL) interconnects. The RDL structure may be formed on the BEOL interconnects, such as on a top metal layer of the BEOL interconnects. The RDL structure may include at least two dielectric layers having metallization features (e.g., vias and traces) embedded therein. A top metal layer of the RDL structure may include active pads or active contacts for forming signal connections with the second wafer. The top metal layer of the RDL structure may include first alignment features, which may be first conductive features. Following bonding, the first alignment features may directly overlap second alignment features of the second wafer. Alignment accuracy may be determined based on accuracy of the overlap between the first and second alignment features. Each pair of overlapping first and second alignment features may be referred to collectively as an alignment mark. Each integrated circuit die region 110 may include an alignment pattern that has at least four alignment marks. Namely, when a single mask exposure is associated with an entire integrated circuit die region 110, each single mask exposure can include an alignment pattern that includes the at least four alignment marks. In some embodiments, at least two of the alignment marks are intra-field alignment marks, meaning that the alignment marks are formed in an active circuit region of the IC die region 110 instead of in a periphery of the IC die region 110 or in a scribe line surrounding the IC die region 110.

In FIG. 1B, a second wafer 104 is provided, corresponding to act 206 of FIG. 2, and the second wafer 104 is bonded to the first wafer 102, corresponding to act 208 of FIG. 2.

The second wafer 104 can be similar in some respects to the first wafer 102, but may include different circuitry or different components than those of the first wafer 102. As one non-limiting example, the first wafer 102 may be bonded to the second wafer 104 to form a complementary metal-oxide-semiconductor (CMOS) image sensor (CIS). In this example, the second wafer 104 may include a backside illumination (BSI) image sensor and the first wafer 102 may include readout and controller circuitry, image processing circuitry, digital signal processor (DSP) circuitry, and the like. Formation of the second wafer 104 may include process operations similar to those described with reference to FIG. 1A, such as etching, deposition, cleaning, planarization, epitaxial growth, and the like.

During bonding, the first wafer 102 may be bonded to the second wafer 104 by a bonding apparatus 120. The bonding apparatus 120 may include a first stage 122, a second stage 124, and a press 126. The first wafer 102 is supported and/or held by the first stage 122. The second wafer 104 is supported and/or held by the second stage 124. The press 126 may be operable to translate the second stage 124 toward the first stage 122 along a third direction D3 (or “vertical direction D3”) to press the first and second wafers 102, 104 together.

In operation, the bonding apparatus 120 can include one or more high-precision alignment mechanisms, such as optical or mechanical structures that improve alignment of alignment features 1021, 1041, 1023, 1043, 1025, 1045 of RDL structures of the first and second wafers 102, 104. The bonding apparatus 120 can apply substantially uniform pressure across surfaces of the first and second wafers 102, 104. For hybrid bonding, dielectric-to-dielectric bonds form initially, then metal-to-metal (e.g., copper-to-copper) bonds form during an annealing operation. The bonding apparatus 120 can include heating capabilities to reach temperatures beneficial for the annealing operation, which is beneficial for hybrid bonding. Temperatures can range from room temperature for initial bonding to around 200° C. to 300° C. or higher for metal diffusion and solidification. In some embodiments, prior to bonding, surfaces of the first and second wafers 102, 104, especially the RDL, are prepared to be flat and clean, which can include performing chemical mechanical polishing (CMP) to recess the alignment features 1021, 1041, 1023, 1043, 1025, 1045 to a level slightly below the dielectric surface to allow for expansion and bonding. To prevent contamination, which can result in void formation or bonding defects, the bonding apparatus 120 can operate in a cleanroom environment or under controlled atmospheric conditions.

During formation of a dielectric bond, oxide layers on the first and second wafers 102, 104 can come into contact with each other and form a weak bond at room or slightly elevated temperatures. Then, the first and second wafers 102, 104 are heated to allow the alignment features 1021, 1041, 1023, 1043, 1025, 1045 to expand, resulting in the structure depicted in FIG. 1C. Although not separately depicted in FIG. 1B, conductive active pads may be included in the first and second wafers 102, 104 that, during bonding, expand, come into contact with each other, and form strong metallic bonds through diffusion.

In FIG. 1C, the first and second wafers 102, 104 are bonded to each other. As depicted, some or all of the alignment features 1021, 1041, 1023, 1043, 1025, 1045 may be misaligned after bonding. For example, the first alignment feature 1021 and the corresponding second alignment feature 1041 are misaligned by a first separation distance S1 along the first direction D1. In another example, the first alignment feature 1023 and the corresponding second alignment feature 1043 are misaligned by a second separation distance S3 along the first direction D1. The first and second separation distances S1, S3 may be a result of linear misalignment, such as translation, rotation or expansion, non-linear misalignment, or both.

In FIG. 1D, linear alignment terms due to misalignment between the alignment features 1023, 1043 are determined, corresponding to act 210 of FIG. 2. As depicted, the first alignment feature 1023 and the second alignment feature 1043 are offset from each other along the first direction D1 due to first translation 130X. The first alignment feature 1023 and the second alignment feature 1043 are offset from each other along the second direction D2 due to second translation 130Y. In some embodiments, the first alignment feature 1023 and the second alignment feature 1043 are offset from each other along the first direction D1 and/or the second direction D2 due to expansion 130N of the first wafer 102, the second wafer 104, or both. The first alignment feature 1023 and the second alignment feature 1043 have angular offset from each other shown by angle θ1 due to rotation 130R of the first wafer 102, the second wafer 104, or both. In addition to the linear effects (e.g., translation, rotation, expansion), the first and second alignment features 1023, 1043 may be offset from each other due to non-linear effects.

In FIG. 1E, infrared (IR) light (or “light in the infrared spectrum”) 1200 is directed toward an alignment mark 1400 including the first and second alignment features 1023, 1043. An image is generated by sensing reflection of the IR light 1200 from the alignment mark 1400. Based on the image, the linear alignment terms may be calculated associated with the alignment mark 1400.

FIG. 1E depicts a keep-out region 1300 that directly overlaps the alignment mark 1400 and extends from an upper surface 104a of the second wafer 104 to a lower surface 102b of the first wafer 102. To avoid scattering of the IR light 1200 and to obtain a clear image of the alignment mark 1400, the keep-out region 1300 is substantially free of circuit features. Namely, the keep-out region 1300 may include only substrates of the first and second wafers 102, 104, the first and second RDLs 102R, 104R, and the alignment mark 1400.

Also depicted in FIG. 1E, the alignment mark 1400 may be adjacent a via position 162 at which a via (e.g., a TSV) is to be formed in a subsequent operation. The via position 162 generally overlaps active circuitry 1029 of the first wafer 102, conductive pads 1027, 1047 and an interconnect structure 1049. The first conductive pad 1027 is positioned in the first RDL 102R and the second conductive pad 1047 is positioned in the second RDL 104R. The interconnect structure 1049 is positioned in the second RDL 104R. An additional interconnect structure may extend from the active circuitry 1029 to the first conductive pad 1027, as depicted by a dashed line.

The alignment mark 1400 is offset from the via position 162 by a distance S6, for example, along the first direction D1. In some embodiments, the distance S6 that separates the alignment mark 1400 from the via position 162 does not exceed about 50 micrometers (μm) to about 100 μm. The distance S6 exceeding about 100 μm may result in insufficiently accurate determination of non-linear alignment terms.

In some embodiments, thickness of the second wafer 104 during imaging of the alignment mark 1400 exceeds about 500 μm, exceeds about 600 μm, exceeds about 700 μm, or another suitable thickness. In some embodiments, the thickness is about 77 5 μm, which can be substantially equal to a thickness of the bare wafer prior to processing thereof that forms the second wafer 104. Namely, imaging of the

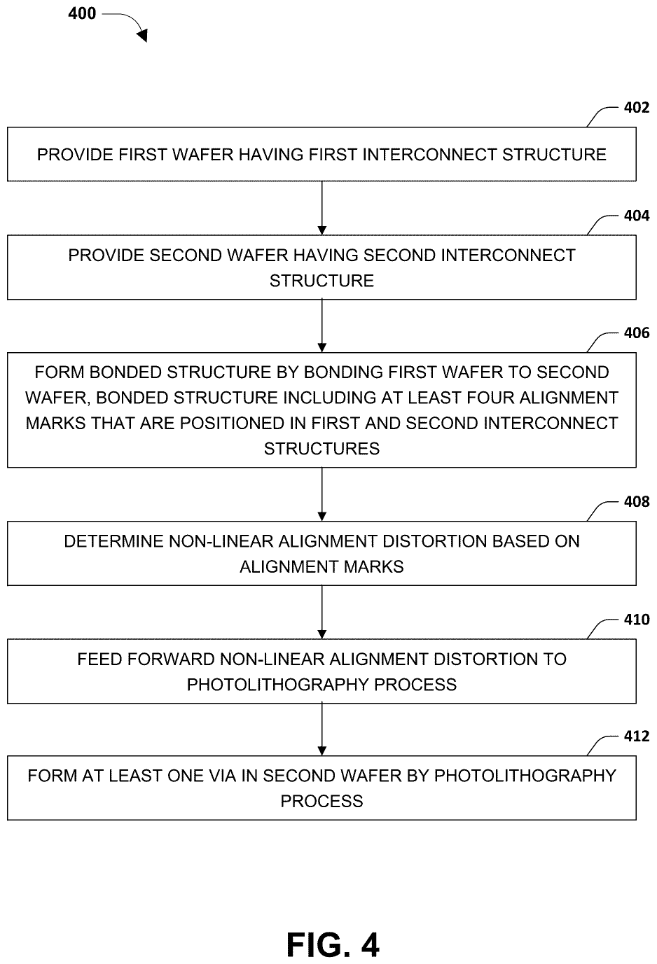

In FIG. 1F, a single field 114 is depicted that includes at least four alignment marks 1400 therein. As one example, the field 114 depicted in FIG. 4 includes seventeen alignment marks 1400. Other numbers of the alignment marks 1400 are contemplated as embodiments herein. The alignment marks 1400 can also be referred to as intra-field alignment marks 1400. By including at least four alignment marks 1400 in each field 114, the non-linear alignment terms can be determined with increased accuracy. In some embodiments, determination of the non-linear alignment terms includes interpolation between offsets determined for at least three of the alignment marks 1400 or at least four of the alignment marks 1400. For example, as depicted in FIG. 1F, a via position 162 may be adjacent a first alignment mark 1400A, a second alignment mark 1400B, a third alignment mark 1400C and a fourth alignment mark 1400D. In some embodiments, alignment accuracy of the via position 162 may be determined by interpolating between offsets associated with each of the first, second, third and fourth alignment marks 1400A, 1400B, 1400C, 1400D. In some embodiments, in addition to or instead of interpolation, other algorithms may be performed to estimate or predict the alignment accuracy of the via position 162. Based on the alignment accuracy of the via position 162 calculated, a non-linear alignment distortion may be fed forward to a photolithography process that forms a via opening associated with the via position 162. The non-linear alignment distortion may be fed forward as part of an alignment accuracy value that also includes linear offset (e.g., translation, rotation, expansion).

In FIG. 1G, each of the alignment marks 1400 may be or include a “box-in-box” shape that includes a first ring or box 1023 and a second ring or box 1043. The first ring 1023 may be positioned in the first RDL 102R described with reference to FIG. 1E, and the second ring 1043 may be positioned in the second RDL 104R. Each of the first ring 1023 and the second ring 1043 may have square shape, rectangular shape, or another suitable shape. In FIG. 1G, the first and second rings 1023, 1043 are depicted having square shape.

The first ring 1023 has first width W1 in the first direction D1 and first length L1 in the second direction D2. The second ring 1043 has second width W2 in the first direction D1 and second length L2 in the second direction D2. In some embodiments, the first width W1 exceeds the second width W2 and the first length L1 exceeds the second length L2. In some embodiments, the first and second widths W1, W2 and the first and second lengths L1, L2 have dimensions in a range of about 15 μm to about 60 μm. The reduced size of the alignment mark 1400 is beneficial to position the alignment mark 1400 inside the field 114, such as in an active circuit region of an IC die 110 in the field 114.

The first ring 1023 has first thickness T1 and the second ring has second thickness T2. In some embodiments, the first thickness T1 is substantially equal to the second thickness T2. The first ring 1023 is separated from the second ring 1043 by a first distance S241 in the first direction D1 and by a second distance S242 in the second direction D2.

Misalignment between the first and second wafers 102, 104 can be determined at least partially based on relative positions and angular offset between the first and second rings 1023, 1043. Translation in the first direction D1 results in increase or decrease in the first distance S241. Translation in the second direction D2 results in increase or decrease in the second distance S242. Rotational misalignment results in angular offset between adjacent sides of the first and second rings 1023, 1043, such that the sides are not parallel to each other.

In FIG. 1H, each of the alignment marks 1400 may be or include a diffraction-based optics (DBO) or micro-DBO (μDBO) pattern. The DBO pattern can include first regions 1410 that include vertical stripes 1412 extending along the second direction D2 and second regions 1420 that include horizontal stripes 1422 extending along the first direction D1. Each first region 1410 may be positioned horizontally adjacent a second region 1420 and vertically adjacent a second region 1420. Each second region 1420 may be positioned horizontally adjacent a first region 1410 and vertically adjacent a first region 1410. A first DBO pattern may be positioned in the first RDL 102R and a second corresponding DBO pattern may be positioned in the second RDL 104R. Alignment accuracy may be determined based on diffraction generated by offset between the corresponding vertical and horizontal stripes 1412, 1422 of the first and second DBO patterns that directly overlap each other. Width and length of the alignment mark 1400 described with reference to FIG. 1H may be similar to that described with reference to FIG. 1G, such as in a range of about 15 μm to about 60 μm.

FIGS. 1I, 1J and 1K depict determination of first non-linear alignment terms and second non-linear alignment terms, corresponding to acts 212 and 214 of FIG. 2.

In FIG. 1I, raw data is obtained that is associated with each alignment mark 1400. The raw data can include first vectors 1450 that indicate direction and magnitude of misalignment associated with each alignment mark 1400. In the illustration of FIG. 1I, raw data is only depicted for a single field 114 for simplicity of illustration. Generally, the raw data is determined for alignment marks 1400 that are distributed throughout all of the fields 114.

In FIG. 1J, linear alignment terms are determined, for example, based on the raw data obtained in FIG. 1I, which can correspond to act 210 of FIG. 2. The linear alignment terms can include translation, rotation, and expansion/contraction and are represented as second vectors 1460 in FIG. 1I. Determination of the linear alignment terms can include performing model fitting, least squares analysis, numerical analysis, algebraic calculation, combinations thereof, and the like. In some embodiments, the determination is performed iteratively.

In FIG. 1K, a residue or distortion is determined by subtracting the linear alignment terms from the raw data. The residue is depicted in FIG. 1J as vectors 1460. The residue can include first non-linear alignment terms and second non-linear alignment terms. In some embodiments, the first non-linear alignment terms are associated with a high-order wafer alignment (HOWA) process. In some embodiments, the second non-linear alignment terms are referred to as correction per exposure (CPE) terms.

HOWA can address misalignment that goes beyond simple linear transformations (e.g., translation, rotation, uniform scaling) by considering higher-order distortions that can include non-linear distortions (e.g., pincushion or barrel distortions) that can occur due to lens aberrations or mechanical stresses, field-dependent distortions, and the like. HOWA can include measuring alignment marks 1400 throughout the field 114 and even across the entire stack of two wafers 102, 104 to capture higher-order distortion information. In some embodiments, one or more models is generated that can predict and correct for the distortions, which can involve polynomial fits or more complex mathematical models to describe the non-linearities. Corrections can then be implemented in a subsequent exposure process, which can include one or more of (i) adjusting the reticle or mask (e.g., moving or deforming the reticle image in real-time to compensate for distortions), (ii) performing stage corrections (e.g., adjusting wafer stage movement during exposure), and (iii) performing lens or mirror adjustments. During the exposure process, a photolithography system, such as a stepper, can dynamically apply corrections based on HOWA data, which can include altering a path of the wafer stage, modifying how the reticle pattern is scanned or stepped across the wafer, making micro-adjustments to the focus or the imaging system to account for field-dependent distortions, and the like.

The CPE terms can be alignment terms that are associated with each individual field 114. The CPE terms can be or include linear distortions or misalignments for each exposure field 114. Namely, relative to the entire wafer stack of the first and second wafers 102, 104, linear distortions or misalignments at the local exposure field 114 can be considered non-linear alignment terms. The CPE terms can be determined based on measurements from alignment marks 1400 within each exposure field 114. Corrections associated with the CPE terms can be applied in a straightforward manner using a linear transformation model.

Because each of the fields 114 includes at least four alignment marks 1400, the CPE terms can be determined with improved accuracy, which is beneficial for correcting overlay in subsequent photolithography processes, such as for forming TSVs.

In FIG. 1L, a thinned wafer 104′ is formed by thinning the second wafer 104, corresponding to act 216 of FIG. 2. The second wafer 104 may be thinned by one or more removal operations. In some embodiments, the thinned wafer 104′ has thickness in a range of about 1 μm to about 50 μm, such as about 1 μm to about 30 μm, about 1 μm to about 15 μm, or another suitable range.

The second wafer 104 may be thinned from, for example, 775 microns down to 1 to 15 microns, such as when the second wafer 104 is or includes a backside illuminated (BSI) image sensor. The thinning can include a series of operations that maintain integrity of the second wafer 104 and the devices fabricated on the front side thereof.

Initially, the second wafer 104 may be placed with its front side 104a exposed (e.g., by using a tape or carrier) on a grinding machine with a coarse-grit grinding wheel. This operation can reduce the thickness of the second wafer 104 to around 100-200 microns. Then, fine grinding may be performed that uses finer grit wheels or pads to further thin the wafer, such as to around 50-100 microns. To polish the wafer to remove any sub-surface damage, achieve target thickness with high precision, and provide a very smooth surface, chemical mechanical planarization (CMP) can be performed. The CMP can include use of a polishing pad and an abrasive slurry. The second wafer 104 is pressed against the pad while rotating, and the slurry, which contains both chemical components to etch the silicon and mechanical abrasives to polish it, removes material uniformly. The CMP can thin the wafer further and is effective down to about 10-50 microns, offering a high degree of flatness and uniformity. In some embodiments, dry etching processes like plasma etching can be employed. This can include reactive ion etching (RIE) or deep reactive ion etching (DRIE), which have benefits of improved precision. RIE or DRIE processes can use plasma to etch silicon atom by atom, allowing control down to a few microns or even sub-micron levels. The etching can be isotropic (uniform in all directions) or anisotropic (directional, typically vertical). After significant thinning, the thinned wafer 104′ may undergo processes that relieve mechanical stress introduced by the thinning process, such as low-temperature annealing or gentle polishing. When the thinned wafer 104′ includes BSI sensors, after thinning, the exposed side of the thinned wafer 104′ may undergo further processing, such as applying anti-reflective coatings, passivation layers, or back-side metallization to improve sensitivity and performance.

In FIG. 1M, a photolithography operation 190 may be performed that exposes fields 114 of the thinned wafer 104′ to prepare the thinned wafer 104′ for formation of TSVs. In some embodiments, the photolithography operation 190 includes determining via positions based on the CPE terms, corresponding to act 218 of FIG. 2.

Forming TSVs after wafer thinning can includes several operations to form vertical electrical connections through the thinned wafer 104′. A layer of photoresist may be applied to the exposed side of the thinned wafer 104′. Then, the photoresist is exposed through a mask to define the via pattern in the photoresist layer. The exposure may be performed field-by-field, with via patterns in each field 114 being exposed at least based on the CPE terms associated with the respective field 114. The exposed photoresist is then developed, leaving openings at the via positions where via openings in which the TSVs will be formed are etched in a subsequent operation. The via openings may be formed by etching through the openings in the patterned photoresist layer, which can include RIE, DRIE or the like. Etch depth may be controlled to reach through the silicon to land on interconnects of the second RDL 104R. Following etching, the patterned photoresist layer is removed via stripping or another suitable operation. The etched thinned wafer 104′ may then be cleaned to remove residues or particles.

In FIG. 1N, TSVs 160 are formed in the via openings at the via positions in the thinned wafer 104′, corresponding to act 220. In some embodiments, forming the TSVs 160 can include depositing a dielectric material (e.g., SiO₂) to line walls of the via openings. The dielectric material may be deposited by chemical vapor deposition (CVD), plasma-enhanced CVD (PECVD) or the like, which is beneficial for improved step coverage. The dielectric material at the bottom of the via opening may be removed selectively to expose the underlying metal layer, such as by anisotropic etching techniques. Then, an optional barrier layer may be formed by depositing a thin layer of a barrier metal, such as titanium nitride (TiN) or tungsten (W) in the via opening on the dielectric material, which can be beneficial to prevent copper diffusion into the surrounding silicon. In some embodiments, a copper seed layer is then applied, which can be via physical vapor deposition (PVD) or another suitable process. The via openings are then filled (e.g., fully or partially) with copper, which can be via an electroplating process. CMP may be performed to remove excess copper and/or barrier metal from the wafer surface of the thinned wafer 104′. In some embodiments, an insulating layer is formed on the wafer surface of the thinned wafer 104′ to protect the TSV 160 from oxidation or contamination.

In FIG. 1O, an optional RDL 104R2 is formed. In some embodiments, additional metal layers 164 are formed to connect the TSVs 160 to each other or to external bond pads.

Following formation of the TSVs 160 and the optional insulating layer, a polymer layer, such as polyimide (PI), benzocyclobutene (BCB), polybenzoxazole (PBO) or the like may be formed via spin coating or lamination. The polymer layer may then be cured to solidify the polymer layer. A photoresist layer is applied over the polymer layer. The photoresist is exposed to, for example, UV light through a mask defining an RDL pattern. Unexposed or exposed areas of the photoresist layer are removed, defining a pattern in the photoresist layer. Portions of the polymer layer exposed by the patterned photoresist layer are then etched to create openings where metal layers 164 will be deposited. The etching dry can include dry etching, such as RIE. After etching, the patterned photoresist layer is stripped, and the polymer layer is cleaned. A thin barrier layer (e.g., Ti/TiN, Ta/TaN) is then optionally deposited to prevent metal diffusion into the polymer layer, which can be performed by PVD or ALD (atomic layer deposition). Then, a thin layer of copper can be applied as a seed layer in the openings in the polymer layer, which can include sputtering or PVD, to serve as an initial layer for electroplating. A second layer of photoresist may be applied, patterned, and developed to define the metal layers 164. Copper may then be deposited selectively onto exposed seed layer areas, filling the patterns defined by the second photoresist layer. After plating, the second photoresist layer is stripped away. Excess seed layer outside the plated areas can be etched away, typically through a selective copper etch process that does not significantly attack the plated copper. CMP may be performed to planarize the copper layer, removing any excess copper and achieving a flat surface for subsequent layers or for bonding. The process just described may be repeated to form additional metal layers of the RDL structure.

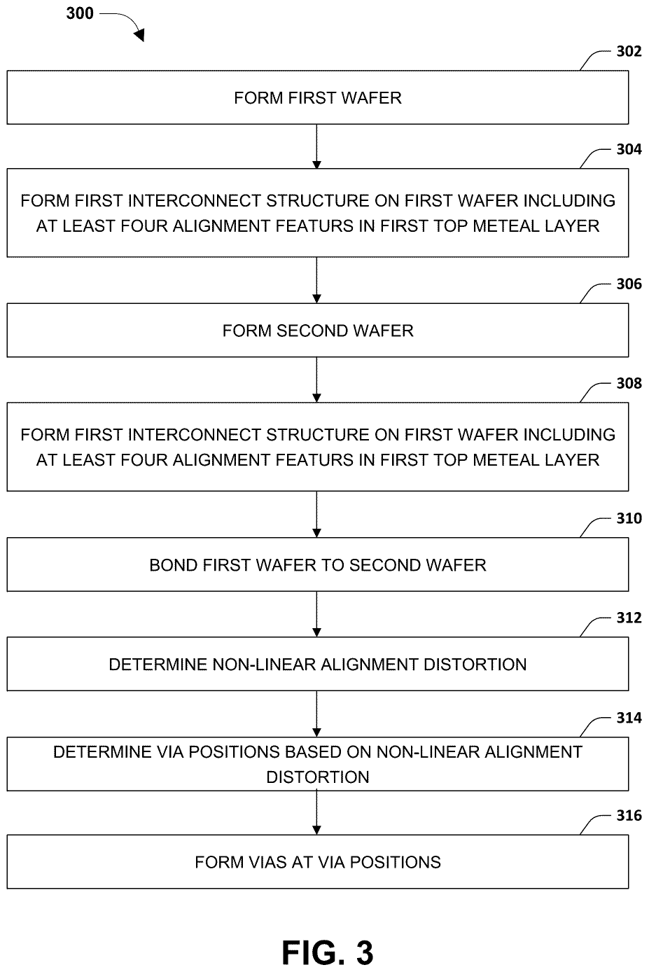

A method 300 is illustrated in FIG. 3 in accordance with some embodiments.

At 302, the method 300 includes forming a first wafer.

At 304, the method 300 includes forming a first interconnect structure on the first wafer, the first interconnect structure including at least four first alignment features in a first top metal layer thereof.

At 306, the method 300 includes forming a second wafer.

At 308, the method 300 includes forming a second interconnect structure on the second wafer, the second interconnect structure including at least four second alignment features in a second top metal layer thereof.

At 310, the method 300 includes bonding the first wafer to the second wafer by forming a hybrid bond between the first interconnect structure and the second interconnect structure, each of the first alignment features overlapping a respective one of the second alignment features.

At 312, the method 300 includes determining non-linear alignment distortion of the first and second wafers based on overlap of the first and second alignment features. In some embodiments, the method 300 includes thinning the second wafer following determining the non-linear alignment distortion, and determining the non-linear alignment distortion includes imaging the first and second alignment features by light having wavelength exceeding about 750 nanometers. In some embodiments, the method 300 includes thinning the second wafer prior to determining the non-linear alignment distortion, and determining the non-linear alignment distortion includes imaging the first and second alignment features by light having wavelength in a range of about 500 nanometers to about 750 nanometers. In some embodiments, the method 300 includes, prior to determining the non-linear alignment distortion, determining linear alignment distortion of the first and second wafers. In some embodiments, determining the non-linear alignment distortion includes performing high-order wafer alignment (HOWA) analysis.

At 314, the method 300 includes determining at least one via position based on the non-linear alignment distortion.

At 316, the method 300 includes forming a via at the at least one via position.

A method 400 is illustrated in FIG. 4 in accordance with some embodiments.

At 402, the method 400 includes providing a first wafer having a first interconnect structure thereon.

At 404, the method 400 includes providing a second wafer having a second interconnect structure thereon.

At 406, the method 400 includes forming a bonded structure by bonding the first wafer to the second wafer including forming a hybrid bond between the first interconnect structure and the second interconnect structure, the bonded structure including at least four alignment marks, each of the alignment marks being positioned in the first interconnect structure and the second interconnect structure. In some embodiments, bonding the first wafer to the second wafer includes forming the alignment marks that are box-in-box alignment marks, each of which includes a first alignment feature positioned in the first interconnect structure and a second alignment feature positioned in the second interconnect structure. In some embodiments, forming the alignment marks includes forming the box-in-box alignment marks, each of which has width and length that each does not exceed about 40 micrometers. In some embodiments, bonding the first wafer to the second wafer includes forming the at least four alignment marks that are each associated with a same integrated circuit die defined in the second wafer.

At 408, the method 400 includes determining non-linear alignment distortion of the first and second wafers based on the alignment marks.

At 410, the method 400 includes feeding forward the non-linear alignment distortion to a photolithography process.

At 412, the method 400 includes forming at least one via in the second wafer by the photolithography process.

In some embodiments, the method 400 includes forming a third interconnect structure on the at least one via. In some embodiments, the method 400 includes bonding a third wafer to the second wafer by the third interconnect structure.

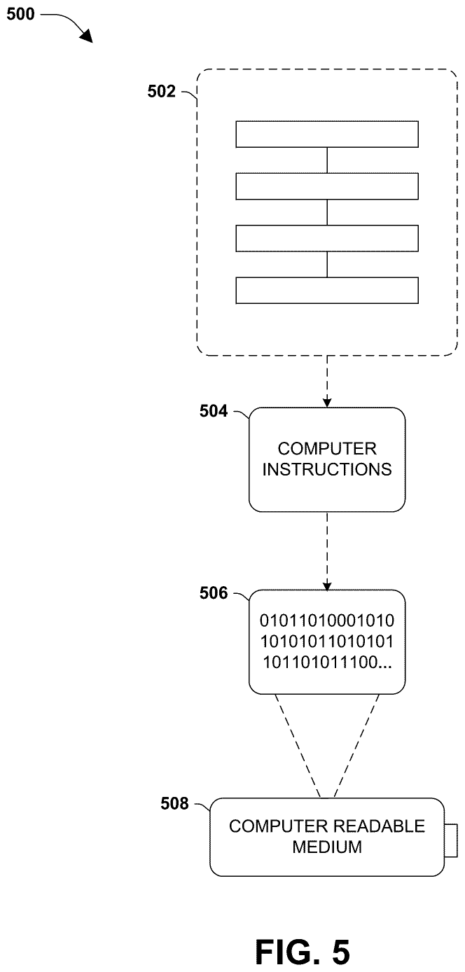

One or more embodiments involve a computer-readable medium comprising processor-executable instructions configured to implement one or more of the techniques presented herein. An exemplary computer-readable medium is illustrated in FIG. 5, wherein the embodiment 500 comprises a computer-readable medium 508 (e.g., a CD-R, DVD-R, flash drive, a platter of a hard disk drive, etc.), on which is encoded computer-readable data 506. This computer-readable data 506 in turn comprises a set of processor-executable computer instructions 504 configured to implement one or more of the principles set forth herein when executed by a processor. In some embodiments 500, the processor-executable computer instructions 504 are configured to implement a method 502, such as at least some of the aforementioned method(s) when executed by a processor. In some embodiments, the processor-executable computer instructions 504 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a device is provided. The device includes: a first substrate; a first interconnect structure on the first substrate; a second substrate; a second interconnect structure on the second substrate, the first substrate being bonded to the second substrate by a hybrid bond between the first interconnect structure and the second interconnect structure; an active circuit region in the second substrate, the active circuit region including a via that extends through the second substrate; and at least four alignment patterns that are offset from the via. Each of the alignment patterns includes: a first conductive feature in a first top metal layer of the first interconnect structure; and a second conductive feature in a second top metal layer of the second interconnect structure, the second conductive feature having size that does not exceed that of the first conductive feature.

In some embodiments, a method is provided. The method includes: forming a first wafer; forming a first interconnect structure on the first wafer, the first interconnect structure including at least four first alignment features in a first top metal layer thereof; forming a second wafer; forming a second interconnect structure on the second wafer, the second interconnect structure including at least four second alignment features in a second top metal layer thereof; bonding the first wafer to the second wafer by forming a hybrid bond between the first interconnect structure and the second interconnect structure, each of the first alignment features overlapping a respective one of the second alignment features; determining non-linear alignment distortion of the first and second wafers based on overlap of the first and second alignment features; determining at least one via position based on the non-linear alignment distortion; and forming a via at the at least one via position.

In some embodiments, a method is provided. The method includes: providing a first wafer having a first interconnect structure thereon; providing a second wafer having a second interconnect structure thereon; forming a bonded structure by bonding the first wafer to the second wafer including forming a hybrid bond between the first interconnect structure and the second interconnect structure, the bonded structure including at least four alignment marks, each of the alignment marks being positioned in the first interconnect structure and the second interconnect structure; determining non-linear alignment distortion of the first and second wafers based on the alignment marks; feeding forward the non-linear alignment distortion to a photolithography process; and forming at least one via in the second wafer by the photolithography process.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A device, comprising:
a first substrate;
a first interconnect structure on the first substrate;
a second substrate;
a second interconnect structure on the second substrate, the first substrate being bonded to the second substrate by a hybrid bond between the first interconnect structure and the second interconnect structure;
an active circuit region in the second substrate, the active circuit region including a via that extends through the second substrate; and
an alignment pattern including at least four alignment marks that are offset from the via, each of the alignment marks including:
a first conductive feature in a first top metal layer of the first interconnect structure; and
a second conductive feature in a second top metal layer of the second interconnect structure, the second conductive feature having size that does not exceed that of the first conductive feature.

2. The device of claim 1, wherein at least two of the alignment marks are positioned in the active circuit region.

3. The device of claim 1, wherein second regions of the second substrate directly overlying the at least four alignment marks do not substantially scatter light in an infrared spectrum.

4. The device of claim 3, wherein first regions of the first substrate directly overlying the at least four alignment marks do not substantially scatter the light in the infrared spectrum.

5. The device of claim 1, wherein at least one of the alignment marks is offset from the via by a distance that does not exceed about 100 micrometers.

6. The device of claim 1, wherein the size of the first conductive feature includes a first dimension that is in a range of about 15 micrometers to about 60 micrometers and a second dimension that is in a range of about 15 micrometers to about 60 micrometers.

7. The device of claim 1, wherein ratio of first thickness of the first substrate over second thickness of the second substrate is in a range of about 1.5 to about 300.

8. A method comprising:
forming a first wafer;
forming a first interconnect structure on the first wafer, the first interconnect structure including at least four first alignment features in a first top metal layer thereof;
forming a second wafer;
forming a second interconnect structure on the second wafer, the second interconnect structure including at least four second alignment features in a second top metal layer thereof;
bonding the first wafer to the second wafer by forming a hybrid bond between the first interconnect structure and the second interconnect structure, each of the first alignment features overlapping a respective one of the second alignment features;
determining non-linear alignment distortion of the first and second wafers based on overlap of the first and second alignment features;
determining at least one via position based on the non-linear alignment distortion; and
forming a via at the at least one via position.

9. The method of claim 8, further comprising:
following determining the non-linear alignment distortion, thinning the second wafer.

10. The method of claim 9, wherein determining the non-linear alignment distortion includes imaging the first and second alignment features by light having wavelength exceeding about 750 nanometers.

11. The method of claim 8, further comprising:
prior to determining the non-linear alignment distortion, thinning the second wafer.

12. The method of claim 11, wherein determining the non-linear alignment distortion includes imaging the first and second alignment features by light having wavelength in a range of about 500 nanometers to about 750 nanometers.

13. The method of claim 8, further comprising:
prior to determining the non-linear alignment distortion, determining linear alignment distortion of the first and second wafers.

14. The method of claim 13, wherein determining the non-linear alignment distortion includes performing high-order wafer alignment analysis.

15. A method, comprising:
providing a first wafer having a first interconnect structure thereon;
providing a second wafer having a second interconnect structure thereon;
forming a bonded structure by bonding the first wafer to the second wafer including forming a hybrid bond between the first interconnect structure and the second interconnect structure, the bonded structure including at least four alignment marks, each of the alignment marks being positioned in the first interconnect structure and the second interconnect structure;
determining non-linear alignment distortion of the first and second wafers based on the alignment marks;
feeding forward the non-linear alignment distortion to a photolithography process; and
forming at least one via in the second wafer by the photolithography process.

16. The method of claim 15, further comprising:
forming a third interconnect structure on the at least one via.

17. The method of claim 16, further comprising:
bonding a third wafer to the second wafer by the third interconnect structure.

18. The method of claim 15, wherein bonding the first wafer to the second wafer includes forming the alignment marks that are box-in-box alignment marks, each of which includes a first alignment feature positioned in the first interconnect structure and a second alignment feature positioned in the second interconnect structure.

19. The method of claim 18, wherein forming the alignment marks includes forming the box-in-box alignment marks, each of which has width and length that each does not exceed about 40 micrometers.

20. The method of claim 15, wherein:
bonding the first wafer to the second wafer includes forming the at least four alignment marks that are each associated with a same integrated circuit die defined in the second wafer.
